(19) United States
(12) Patent Application Publication
(10) Pub. No.: US 2024/0258083 A1
(43) Pub. Date: Aug. 1, 2024

(54) SUBSTRATE PROCESSING APPARATUS AND SUBSTRATE SUPPORT

(71) Applicant: Tokyo Electron Limited, Tokyo (JP)

(72) Inventors: Makoto KATO, Miyagi (JP); Ryoma MUTO, Miyagi (JP); Kaisei SUGA, Miyagi (JP)

(73) Assignee: Tokyo Electron Limited, Tokyo (JP)

(21) Appl. No.: 18/423,391

(22) Filed: Jan. 26, 2024

(30) Foreign Application Priority Data
Jan. 26, 2023 (JP) 2023-010032

(51) Int. Cl. H01J 37/32

(52) U.S. Cl. CPC H01J 37/32724; H01J 37/32082; H01J 2237/002; H01J 2237/2007

(57) ABSTRACT

There is a substrate processing apparatus comprising: a processing chamber; a substrate support disposed in the chamber; and a power supply configured to supply a radio frequency (RF) power to at least the substrate support, wherein the substrate support includes: an electrostatic chuck that is made of ceramic and holds a substrate by electrostatic attraction; a base that has a channel through which a heat exchange medium flows and supports the electrostatic chuck; a low linear expansion coefficient member disposed between the electrostatic chuck and the base; a heat transfer sheet disposed between the low linear expansion coefficient member and the base; a fixing part configured to fix the heat transfer sheet to the low linear expansion coefficient member; and a conductive member that is disposed between the low linear expansion coefficient member and the base and electrically connects the low linear expansion coefficient member and the base.

### CROSS-REFERENCE TO RELATED APPLICATION

This application claims priority to Japanese Patent Application No. 2023-010032 filed on Jan. 26, 2023, the entire contents of which are incorporated herein by reference.

### TECHNICAL FIELD

The present disclosure relates to a substrate processing apparatus and a substrate support.

### BACKGROUND

A substrate to be processed on an electrostatic chuck is cooled to a desired temperature by allowing a temperature-controlled heat exchange medium to flow from a chiller unit to a channel of a substrate support. For example, Japanese Laid-open Patent Publication No. 2016-27601 proposes a substrate processing apparatus including a substrate support on which a substrate to be processed is placed. The substrate support includes a base where a channel through which a temperature-controlled heat exchange medium flows is formed, and an electrostatic chuck having an electrode embedded in ceramic with high plasma resistance and having a placing surface on which the substrate to be processed is placed. The substrate support has a structure in which the base and the electrostatic chuck are bonded with an adhesive layer.

Recently, a radio frequency (RF) power applied to the substrate support is increasing. Therefore, heat input from plasma to the substrate increases, so that the temperature control of the substrate may be insufficient.

### SUMMARY

The present disclosure provides a technique capable of enhancing the temperature control efficiency of the substrate support.

In accordance with an aspect of the present disclosure, there is a substrate processing apparatus comprising: a processing chamber; a substrate support disposed in the processing chamber; and a power supply configured to supply a radio frequency (RF) power to at least the substrate support, wherein the substrate support includes: an electrostatic chuck that is made of ceramic and holds a substrate to be processed by electrostatic attraction; a base that has a channel through which a heat exchange medium flows and supports the electrostatic chuck; a low linear expansion coefficient member disposed between the electrostatic chuck and the base; a heat transfer sheet disposed between the low linear expansion coefficient member and the base; a fixing part configured to fix the heat transfer sheet to the low linear expansion coefficient member; and a conductive member that is disposed between the low linear expansion coefficient member and the base and electrically connects the low linear expansion coefficient member and the base.

### BRIEF DESCRIPTION OF THE DRAWINGS

FIG. 1 is a schematic cross-sectional view showing an example of a plasma processing apparatus according to an embodiment.

FIGS. 2A to 2C show configurations of substrate supports according to first and second embodiments and a reference example.

FIG. 3 is a view taken along III-III plane of FIG. 1.

FIGS. 4A to 4C show an example of an electrode structure of the substrate support according to the first embodiment.

FIGS. 5A to 5C show an example of an electrode structure of the substrate support according to the second embodiment.

### DETAILED DESCRIPTION

Hereinafter, embodiments of the present disclosure will be described in detail with reference to the accompanying drawings. Like reference numerals will be given to like parts throughout the drawings, and redundant description thereof may be omitted.

### (Plasma Processing Apparatus)

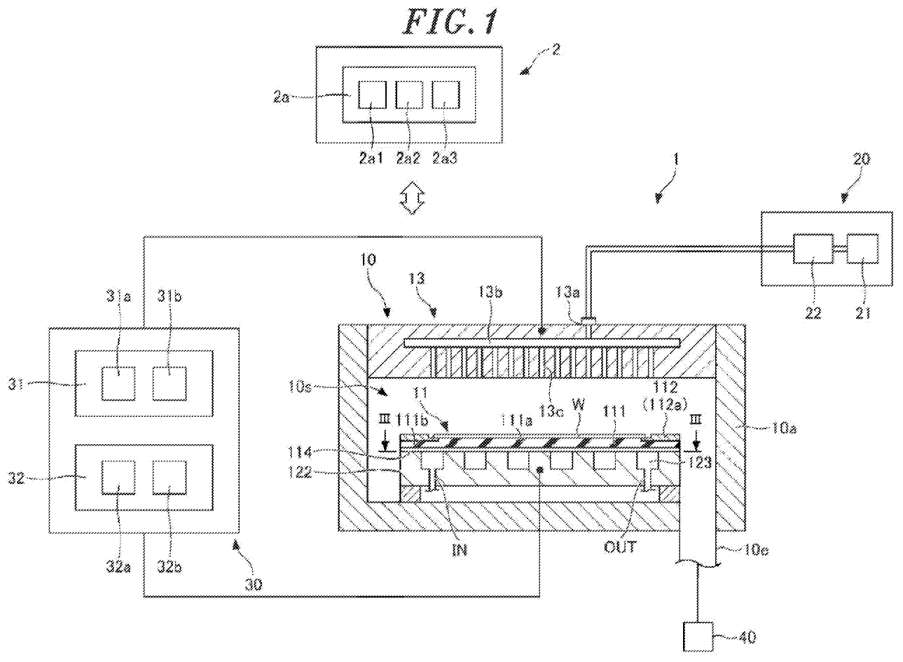

Hereinafter, a configuration example of a plasma processing apparatus will be described with reference to FIG. 1. The plasma processing apparatus shown in FIG. 1 is a capacitively coupled plasma processing apparatus 1, and includes a controller 2. The plasma processing apparatus 1 shown in FIG. 1 is an example of a substrate processing apparatus. The plasma processing apparatus 1 includes a plasma processing chamber 10 (processing container), a gas supply part 20, a power supply part 30, and an exhaust system 40. Further, the plasma processing apparatus 1 includes a substrate support 11 and a gas introducing part. The gas introducing part is configured to introduce at least one processing gas into the plasma processing chamber 10. The gas introducing part includes a shower head 13. The substrate support 11 is disposed in the plasma processing chamber 10. The shower head 13 is disposed above the substrate support 11. In one embodiment, the shower head 13 forms at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas to the plasma processing space 10s, and at least one gas exhaust port for discharging a gas from the plasma processing space 10s. The sidewall 10a is grounded. The shower head 13 and the substrate support 11 are electrically insulated from a housing of the plasma processing chamber 10.

The substrate support 11 includes a base 122, a low linear expansion coefficient member 114, and an electrostatic chuck 111. The substrate support 11 further includes a ring assembly 112. The ring assembly 112 includes one or multiple annular members. At least one of the annular members is an edge ring 112a. The electrostatic chuck 111 is disposed above the base 122 with the low linear expansion coefficient member 114 interposed therebetween, and has a central region (substrate supporting surface 111a) for supporting a substrate to be processed (wafer) (hereinafter, referred to as “substrate W”) and an annular region (ring supporting surface 111b) for supporting the edge ring 112a. The annular region (the ring supporting surface 111b) of the electrostatic chuck 111 surrounds the central region (the substrate supporting surface 111a) of the electrostatic chuck 111 in plan view. The substrate W is placed on the substrate supporting surface 111a of the electrostatic chuck 111, and the edge ring 112a is placed on the ring supporting surface 111b of the electrostatic chuck 111 to surround the substrate W on the substrate supporting surface 111a of the electrostatic chuck 111. In one embodiment, the base 122 includes a conductive member. The conductive member of the base 122 functions as a lower electrode. The electrostatic chuck 111 is disposed over the base 122 with the low linear expansion coefficient member 114 interposed therebetween. The upper surface of the electrostatic chuck 111 has the substrate supporting surface 111a. Further, the substrate support 11 may include a temperature control module configured to adjust at least one of the electrostatic chuck 111, the edge ring 112a, and the substrate W to a target temperature. The temperature control module may include a channel 123, a heater, a heat transfer medium, or a combination thereof. Although the channel 123 is formed in the base 122 in the embodiment, the present disclosure is not limited thereto. The heat exchange medium flows through the channel 123. The heat exchange medium is liquid. The heat exchange medium whose temperature has been controlled by a chiller unit (not shown) flows in the channel 123 from an inlet IN of the substrate support 11 through a line, thereby cooling the substrate W on the electrostatic chuck 111 to a desired temperature. The heat exchange medium flowing through the channel 123 returns to the chiller unit through the line from an outlet OUT of the substrate support 11, is subjected to temperature control, and then flows through the channel 123 again. Further, the substrate support 11 may include a heat transfer gas supply part configured to supply a heat transfer gas to the gap between the bottom surface of the substrate W and the substrate supporting surface 111a.

The shower head 13 is configured to introduce at least one processing gas from the gas supply part 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b, and is introduced into the plasma processing space 10s from the gas inlets 13c. Further, the shower head 13 includes a conductive member. The conductive member of the shower head 13 functions as an upper electrode. The gas introducing part may include, in addition to the shower head 13, one or more side gas injectors (SGI) attached to one or multiple openings formed in the sidewall 10a.

The gas supply part 20 may include at least one gas source 21 and at least one flow rate controller 22. In one embodiment, the gas supply part 20 is configured to supply at least one processing gas from a corresponding gas source 21 to the shower head 13 via a corresponding flow rate controller 22. Each of the flow rate controllers 22 may include, for example, a mass flow controller or a pressure-controlled flow rate controller. Further, the gas supply part 20 may include one or more flow modulation devices for modulating or pulsating the flow rate of at least one processing gas.

The power supply part 30 includes an RF power supply 31 connected to plasma processing chamber 10 via at least one impedance matching circuit. The RF power supply 31 is configured to supply at least one RF signal (RF power), such as a source RF signal (RF source power) and a bias RF signal (RF bias power), to the conductive member of substrate support 11 and/or the conductive member of the shower head 13. Accordingly, plasma is generated from at least one processing gas supplied to the plasma processing space 10s. Hence, the RF power supply 31 may function as at least a part of a plasma generator configured to generate plasma from one or more processing gases in plasma processing chamber 10. Further, by supplying a bias RF signal to the conductive member of the substrate support 11, a bias potential is generated at the substrate W, and ion components in the generated plasma can be attracted to the substrate W.

In one embodiment, the RF power supply 31 includes a first RF generator 31a and a second RF generator 31b. The first RF generator 31a is connected to the conductive member of the substrate support 11 and/or the conductive member of the shower head 13 via at least one impedance matching circuit, and is configured to generate a source RF signal (RF source power) for plasma generation. In one embodiment, the source RF signal has a frequency within a range of 13 MHz to 150 MHz. In one embodiment, the first RF generator 31a may be configured to generate multiple source RF signals having different frequencies. The generated one or multiple source RF signals are provided to the conductive member of the substrate support 11 and/or the conductive member of the shower head 13. The second RF generator 31b is connected to the conductive member of the substrate support 11 via at least one impedance matching circuit, and is configured to generate a bias RF signal (RF bias power). In one embodiment, the bias RF signal has a frequency lower than that of the source RF signal. In one embodiment, the bias RF signal has a frequency within a range of 400 kHz to 13.56 MHz. In one embodiment, the second RF generator 31b may be configured to generate multiple bias RF signals having different frequencies. The generated one or multiple bias RF signals are provided to the conductive member of the substrate support 11. In various embodiments, at least one of the source RF signal and the bias RF signal may pulsate.

The power supply part 30 may include a DC power supply 32 connected to the plasma processing chamber 10. The DC power supply 32 includes a first DC generator 32a and a second DC generator 32b. In one embodiment, the first DC generator 32a is connected to the conductive member of the substrate support 11, and is configured to generate a first DC signal. The generated first DC signal (first bias DC signal) is applied to the conductive member of the substrate support 11. In one embodiment, the first DC signal may be applied to another electrode, such as an electrode in the electrostatic chuck 111. In one embodiment, the second DC generator 32b is connected to the conductive member of the shower head 13, and is configured to generate a second DC signal. The generated second DC signal is applied to the conductive member of the shower head 13. In various embodiments, at least one of the first DC signal and the second DC signal may pulsate. The first and second DC generators 32a and 32b may be provided in addition to the RF power supply 31, or the first DC generator 32a may be provided instead of the second RF generator 31b.

The exhaust system 40 may be connected to a gas exhaust port 10e disposed at the bottom portion of the plasma processing chamber 10, for example. The exhaust system 40 may include a pressure control valve and a vacuum pump. The pressure in the plasma processing space 10s is adjusted by the pressure control valve. The vacuum pump may include a turbo molecular pump, a dry pump, or a combination thereof.

The controller 2 processes computer-executable instructions that cause the plasma processing apparatus 1 to perform various steps described in the present disclosure. The controller 2 may be configured to control individual elements of the plasma processing apparatus 1 to perform various steps described herein. In one embodiment, the controller 2 may be partially or entirely included in the plasma processing apparatus 1. The controller 2 may include, for example, a computer 2a. The computer 2a may include, for example, a processing part (central processing unit (CPU)) 2a1, a storage part 2a2, and a communication interface 2a3. The processing part 2a1 may be configured to perform various control operations based on programs stored in the storage part 2a2. The storage part 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN) or the like.

### (Substrate Support)

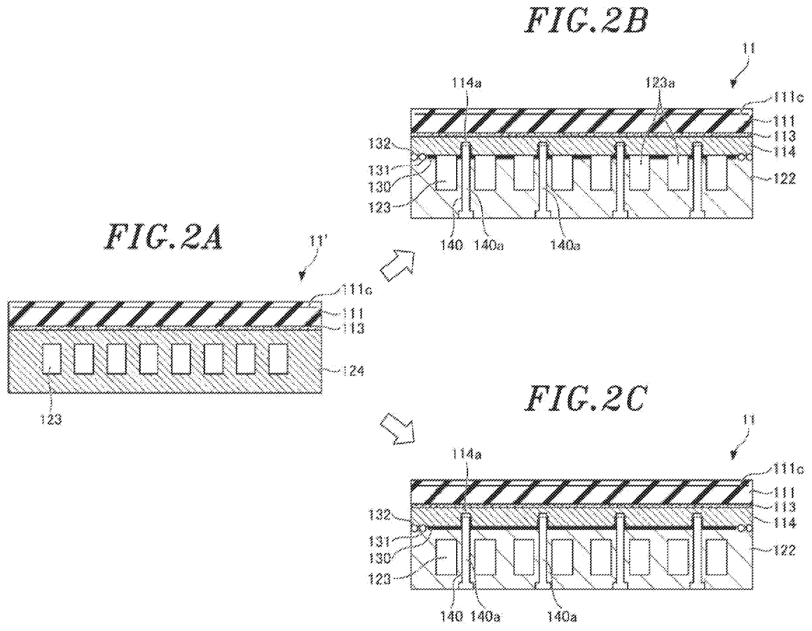

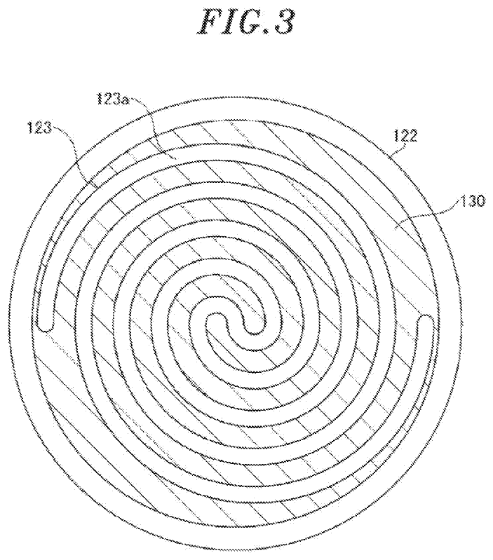

The configuration of the substrate support 11 will be further described with reference to FIGS. 1 to 3. FIGS. 2A to 2C show the configuration of the substrate support 11 according to the first and second embodiments and a substrate support 11′ of a reference example. FIG. 3 is a view taken along III-III plane of FIG. 1, and is a plan view of the base 122 viewed from above.

FIG. 2A shows the substrate support 11′ of the reference example. FIG. 2B shows the configuration example of the substrate support 11 according to the first embodiment. FIG. 2C shows the configuration example of the substrate support 11 according to the second embodiment.

The substrate support 11′ of the reference example shown in FIG. 2A includes the electrostatic chuck 111 and a base 124. The electrostatic chuck 111 is made of ceramic and has an attracting electrode 111c therein. By applying a DC voltage to the attracting electrode 111c, the electrostatic chuck 111 holds the substrate W by electrostatic attraction.

The base 124 is made of metal matrix composites (MMC), which is a low linear expansion coefficient member, and has the channel 123 therein. A metal bonding layer 113 is disposed between the electrostatic chuck 111 and the base 124. The metal bonding layer 113 performs metal bonding of the electrostatic chuck 111 and the base 124 by metal brazing.

Also with the configuration of the substrate support 11′ of the reference example, the substrate W on the electrostatic chuck 111 is cooled to a desired temperature by allowing the heat exchange medium whose temperature is controlled by the chiller unit to flow through the channel 123 of the base 124. However, recently, a radio frequency power applied to the substrate support has been increasing in view of reduction of substrate processing time (etching time, or the like) and straightness of ions. Therefore, heat input from the plasma to the substrate W increases, so that the temperature control of the substrate W may be insufficient. When the control of the temperature of the substrate W is insufficient, the efficiency of processing such as etching or the like may decrease due to an increase in the temperature of the substrate W, and the substrate W may be damaged by heat.

Therefore, in the first and second embodiments shown in FIGS. 2B and 2C, the substrate support 11 capable of improving the temperature control efficiency of the substrate W and the plasma processing apparatus 1 are provided.

### First Embodiment

### Configuration Example

The substrate support 11 according to the first embodiment shown in FIG. 2B has the electrostatic chuck 111, the base 122, the low linear expansion coefficient member 114, a heat transfer sheet 130, a fixing part 140, the metal bonding layer 113, and a conductive gasket 131.

The electrostatic chuck 111 is made of a dielectric, and has the attracting electrode 111c therein. By applying a DC voltage (DC bias voltage, first bias DC signal) from the power supply part 30 (the DC power supply 32 of FIG. 1) to the attracting electrode 111c, the electrostatic chuck 111 holds the substrate W on the substrate supporting surface 111a by electrostatic attraction.

The base 122 is made of a non-magnetic metal material, and has the channel 123 therein. The low linear expansion coefficient member 114 is disposed between the electrostatic chuck 111 and the base 122.

The channel 123 formed in the base 122 is opened on the upper surface of the base 122. An opening 123a on the upper surface of the channel 123 is blocked by the low linear expansion coefficient member 114. In other words, the upper surface of the channel 123 is in contact with the bottom surface of the low linear expansion coefficient member 114.

FIG. 3 shows the upper surface (III-III plane of FIG. 1) of the base 122. The channel 123 is formed in a spiral shape in the base 122, and the opening 123a of the spiral channel 123 is formed in the upper surface of the base 122.

Accordingly, the temperature of the substrate W can be controlled on the entire substrate supporting surface 111a (see FIG. 1) of the substrate support 11. The shape of the channel 123 is not limited to a spiral shape, and may be a radial shape or other shapes.

The heat transfer sheet 130 is disposed between the low linear expansion coefficient member 114 and the base 122. The heat transfer sheet 130 is a circular sheet, and has an opening having the same shape as that of the opening 123a of the channel 123. The diameter of the heat transfer sheet 130 is smaller than those of the low linear expansion coefficient member 114 and the base 122, and the outermost periphery of the heat transfer sheet 130 is located on the inner side of the outermost peripheries of the low linear expansion coefficient member 114 and the base 122. The heat transfer sheet 130 is a graphite sheet. The graphite sheet is made of a resin material in which carbon and silicon are combined, and has high thermal conductivity. Therefore, as shown in FIG. 3, the heat transfer sheet 130 is disposed on the entire upper surface of the base 122 where the opening 123a of the channel 123 is not formed. Accordingly, the heat transfer efficiency between the low linear expansion coefficient member 114 and the base 122 can be increased, and the cooling performance of the channel 123 can be improved.

The heat transfer sheet 130 may be an anisotropic heat transfer sheet containing graphite. In other words, the heat transfer sheet 130 may be made of a sheet-shaped anisotropic material such as graphite, which can ensure high thermal conductivity, because carbon crystal structures in a horizontal direction or carbon crystal structures in a vertical direction are tightly bound by covalent bonds. Accordingly, horizontal heat conduction or vertical heat conduction can be improved, and the in-plane temperature uniformity on the substrate W can be improved.

As shown in FIGS. 2A to 2C, the fixing part 140 may have a screw structure including, for example, a plurality of screws 140a. The fixing part 140 may fix the heat transfer sheet 130 to the low linear expansion coefficient member 114 by inserting the screws 140a into through-holes penetrating through the base 122 in a thickness direction and screw-fixing the tip ends thereof to screw holes 114a formed in the low linear expansion coefficient member 114. The number and arrangement of the screws 140a are determined such that the entire surface of the heat transfer sheet 130 is uniformly pressurized. Hence, the heat transfer sheet 130 can realize stable heat transfer between the base 122, the low linear expansion coefficient member 114, and the electrostatic chuck 111.

The fixing part 140 is not limited to a screw structure, and may have another structure as long as the entire surface of the heat transfer sheet 130 can be uniformly pressurized and fixed to the low linear expansion coefficient member 114. For example, the fixing part 140 may have a clamp structure, and may fix the heat transfer sheet 130 to the low linear expansion coefficient member 114 by sandwiching the low linear expansion coefficient member 114 and the base 122 with a clamp.

When the solid part of the low linear expansion coefficient member 114 and the solid part of the base 122 are brought into contact with each other without using the heat transfer sheet 130, a small space is generated on the contact surface, which increases the thermal resistance and reduces the heat transfer property. Therefore, the heat transfer sheet 130 is disposed between the low linear expansion coefficient member 114 and the base 122, and the entire surface of the heat transfer sheet 130 is pressurized by the fixing part 140. Accordingly, the gap between the low linear expansion coefficient member 114 and the base 122 is eliminated and the thermal resistance is lowered, thereby improving the heat conduction. Hence, the heat transfer efficiency between the low linear expansion coefficient member 114 and the base 122 can be increased, and the cooling performance of the channel 123 is increased, which makes it possible to promote the decrease in the temperature of the substrate W, and control the temperature of the substrate W with high accuracy.

The metal bonding layer 113 is disposed between the electrostatic chuck 111 and the low linear expansion coefficient member 114. The metal bonding layer 113 bonds (metal-bonds) the electrostatic chuck 111 and the base 122 by brazing (metal brazing). Accordingly, the thermal resistance between the electrostatic chuck 111 and the low linear expansion coefficient member 114 is decreased, thereby improving heat conduction and further promoting the temperature control of the substrate W. Hence, it is possible to provide the substrate support 11 having the electrostatic chuck 111 and the base 122 with high thermal conductivity.

As shown in FIG. 2, the conductive gasket 131 is disposed on the outer periphery of the heat transfer sheet 130 fixed between the base 122 and the low linear expansion coefficient member 114 to surround the heat transfer sheet 130. A vacuum seal 132 is disposed on the outer periphery of the conductive gasket 131 to surround the conductive gasket 131. The vacuum seal 132 is, for example, an O-ring.

The conductive gasket 131 is disposed between the low linear expansion coefficient member 114 and the base 122, and electrically connects the low linear expansion coefficient member 114 and the base 122. The vacuum seal 132 seals the plasma processing space 10s in a vacuum (decompressed) atmosphere from the space on the channel 123 side. Further, the vacuum seal 132 may be plasma resistant. Accordingly, the conductive gasket 131 and the heat transfer sheet 130 can be protected from consumption by the plasma generated in the plasma processing space 10s. In particular, the heat transfer sheet 130, which is a graphite sheet containing carbon, is likely to be consumed by plasma. Further, the conductive gasket 131 is made of a metal. Therefore, by performing sealing using the vacuum seal 132, the consumption of the conductive gasket 131 and the heat transfer sheet 130 can be suppressed, thereby preventing the conductive gasket 131 and the heat transfer sheet 130 from causing contamination.

### Material Example

The electrostatic chuck 111 is made of ceramic such as alumina (Al₂O₃) having high plasma resistance or the like. The base 122 may be made of a material having a volume resistivity of less than 10⁻⁴ Ωm. In this case, the power loss of the RF signal in the base 122 can be further reduced. For example, the base 122 may be aluminum, molybdenum, or titanium.

The low linear expansion coefficient member 114 may be made of a material whose linear expansion coefficient difference from the electrostatic chuck 111 is 2 ppm/° C. or less. For example, the low linear expansion coefficient member 114 may be metal matrix composites (MMC) or molybdenum. In this case, the difference in the linear expansion coefficients between the base 122 and the low linear expansion coefficient member 114 can be further reduced, and shear stress caused by temperature changes can be suppressed.

The conductive gasket 131 may be a spring-shaped conductive member or a spiral-shaped metal. The conductive gasket 131 is an example of a conductive member that electrically connects the low linear expansion coefficient member 114 and the base 122. The base 122 also functions as a lower electrode that supplies an RF power. Therefore, for example, when the RF power is supplied to the base 122 made of aluminum, the conductive gasket 131 is configured to transmit an RF current to the electrostatic chuck 111 and the low linear expansion coefficient member 114 on the base 122. The conductive gasket 131 can form a conductive path between the base 122 and the electrostatic chuck 111.

The heat transfer sheet 130 includes a resin material in which carbon and silicon are combined to improve an adhesive property and a heat transfer property. Thus, the heat transfer sheet 130 with a high adhesive property and a high heat transfer property tends to have low conductivity. On the contrary, the conductive gasket 131 with high thermal conductivity tends to have a low heat transfer property. From the above, the heat transfer sheet 130 having a high adhesive property and a high heat transfer property is provided, and the conductive gasket 131 is configured to form a conductive path between the base 122 and the electrostatic chuck 111.

However, the conductive member that electrically connects the low linear expansion coefficient member 114 and the base 122 is not limited to the conductive gasket 131. The conductive screws 140a may be used, or both the conductive gasket 131 and the conductive screws 140a may be used. Accordingly, the cooling performance of the channel 123 can be improved, and the accuracy of temperature control of the substrate W can be improved.

Further, in the substrate support 11 according to the first embodiment shown in FIG. 2B, the channel 123 is formed at the upper surface of the base 122. Thus, the processing cost of the substrate support 11 is lower than that of the substrate support 11′ of the reference example shown in FIG. 2A in which the channel 123 is formed in the base 124. In addition, the processing coat of the base 122 made of aluminum shown in FIG. 2B is lower than that of the base 124 made of MMC shown in FIG. 2A, because it is easier to process the channel 123 in the base 122 made of aluminum.

### Second Embodiment

The basic configuration of the substrate support 11 according to the second embodiment shown in FIG. 2C is the same as that of the substrate support 11 according to the first embodiment. The substrate support 11 according to the first embodiment in which the upper surface of the channel 123 is blocked by the low linear expansion coefficient member 114 is different from the substrate support 11 according to the second embodiment in which the upper surface of the channel 123 is blocked at the upper part of the base 122. Therefore, different configurations will be described, and description of the other configurations will be omitted.

For example, a fluorine-based heat exchange medium such as brine or the like flows through the channel 123. Therefore, in the configuration of the substrate support 11 according to the first embodiment, the heat transfer sheet 130 may deteriorate due to the direct contact with brine.

On the other hand, in the configuration of the substrate support 11 according to the second embodiment, the upper surface of the channel 123 is blocked at the upper part of the base 122, so that brine is not brought into direct contact with the heat transfer sheet 130, thereby preventing deterioration of the heat transfer sheet 130. Further, due to the presence of the base 122 made of a non-magnetic metal such as aluminum with high thermal conductivity (high thermal diffusion) on the channel 123, heat is likely to spread in the horizontal direction. Therefore, the temperature uniformity is increased, and the occurrence of temperature singularities due to the arrangement or shape of the channel 123 can be suppressed. In addition, the processing coat of the base 122 made of aluminum shown in FIG. 2C is lower than that of the base 124 made of MMC shown in FIG. 2A, because it is easier to process the channel 123 in the base 122 made of aluminum.

### <Electrode Structures of First and Second Embodiments>

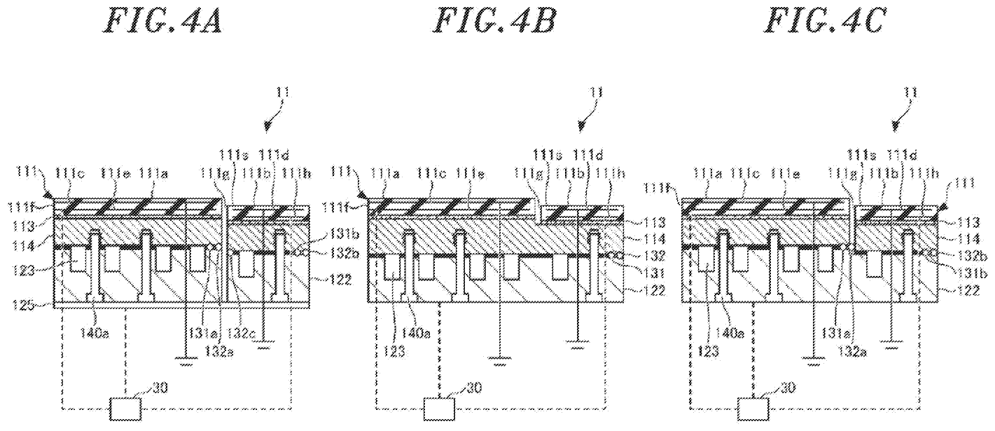

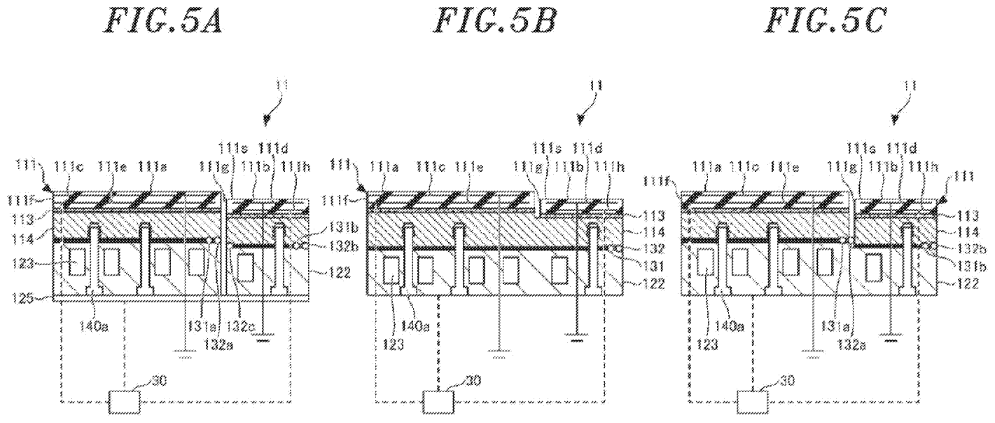

The power supply part 30 may supply an RF source power (source RF signal), and an RF bias power (bias RF signal) or a DC bias voltage to the base 122. An electrode structure that is applicable to the substrate support 11 according to the first embodiment and the substrate support 11 according to the second embodiment in order to supply the power will be described with reference to FIGS. 4A to 4C and 5A to 5C. FIGS. 4A to 4C show examples of the electrode structure of the substrate support 11 according to the first embodiment. FIGS. 5A to 5C show examples of the electrode structure of the substrate support 11 according to the second embodiment.

As shown in FIGS. 4A to 4C and 5A to 5C, the electrostatic chuck 111 may include a first portion 111f having the substrate supporting surface 111a for supporting the substrate W, and a second portion 111s having the ring supporting surface 111b for supporting the edge ring 112a. An annular gap 111g exists between the first portion 111f and the second portion 111s of the electrostatic chuck 111, and the first portion 111f and the second portion 111s of the electrostatic chuck 111 are separated.

The attracting electrode 111c and a first bias electrode 111e disposed below the attracting electrode 111c are disposed at the first portion 111f of the electrostatic chuck 111. An attracting electrode 111d and a second bias electrode 111h disposed below the attracting electrode 111d are disposed at the second portion 111s of the electrostatic chuck 111.

The annular gap 111g has the smallest depth in the substrate support 11 of FIGS. 4B and 5B, has the largest depth in the substrate support 11 of FIGS. 4A and 5A, and has an intermediate depth in the substrate support 11 of FIGS. 4C and 5C. However, the present disclosure is not limited thereto. The annular gap 111g may extend from the bottom surface of the base 122 to one of the substrate supporting surface 111a or the ring supporting surface 111b.

In the substrate support 11 of FIGS. 4B and 5B, the metal bonding layer 113 is separated to correspond to the position where the first portion 111f and the second portion 111s of the electrostatic chuck 111 are separated. Hence, depth/the bottom surface of the gap 111g has the same height as that of the bottom surface of the metal bonding layer 113.

In the substrate support 11 of FIGS. 4C and 5C, the low linear expansion coefficient member 114 is also separated to correspond to the position where the metal bonding layer 113 is separated. Accordingly, depth/the bottom surface of the gap 111g has the same height as that of the bottom surface of the low linear expansion coefficient member 114. In this case, a conductive gasket 131a and a vacuum seal 132a are disposed at the outer periphery of the heat transfer sheet 130 disposed below the first portion 111f of the electrostatic chuck 111 to surround the heat transfer sheet 130. Further, a conductive gasket 131b and a vacuum seal 132b are disposed at the outer periphery of the heat transfer sheet 130 disposed below the second portion 111s of the electrostatic chuck 111 to surround the heat transfer sheet 130. Accordingly, it is possible to protect the conductive gasket 131a, the conductive gasket 131b, and the heat transfer sheet 130 from the consumption by the plasma generated in the plasma processing space 10s.

In the substrate support 11 of FIGS. 4A and 5A, the base 122 is also separated to correspond to the position where the low linear expansion coefficient member 114 is separated. Accordingly, depth/the bottom surface of the gap 111g has the same height as that of the bottom surface of the base 122. In this case, a conductive plate 125 is disposed below the base 122 to block the gap 111g. Further, the conductive gasket 131a and the vacuum seal 132a are disposed at the outer periphery of the heat transfer sheet 130 disposed below the first portion 111f of the electrostatic chuck 111 to surround the heat transfer sheet 130. The conductive gasket 131b and the vacuum seal 132b are disposed at the outer periphery of the heat transfer sheet 130 disposed below the second portion 111s of the electrostatic chuck 111 to surround the heat transfer sheet 130. Further, a vacuum seal 132c is disposed at the inner periphery of the heat transfer sheet 130 disposed below the second portion 111s of the electrostatic chuck 111 to surround the heat transfer sheet 130. Accordingly, the conductive gasket 131a, the conductive gasket 131b, and the heat transfer sheet 130 can be protected from the consumption by the plasma generated in the plasma processing space 10s.

As shown in FIG. 1, the first portion 111f and the second portion 111s of the electrostatic chuck 111 may be integrated. The power supply part 30 supplies an RF power to the base 122 regardless of whether the electrostatic chuck 111 is integrated or separated (see FIGS. 4 and 5). The RF power supplied to the base 122 may be one or both of an RF source power and an RF bias power. An RF bias power or a DC bias power may be supplied to the electrode disposed in the first portion 111f and/or the second portion 111s of the electrostatic chuck 111 regardless of whether the electrostatic chuck 111 is integrated or separated.

As a first example of the supply of an RF power and/or a DC voltage, in the integrated electrostatic chuck 111 (see FIG. 1), an RF source power and an RF bias power may be supplied from the power supply part 30 to the base 122. In this case, a DC voltage may be supplied to the attracting electrode 111c, and the substrate W may be electrostatically attracted to the electrostatic chuck 111. A DC voltage may be supplied to each of the attracting electrode 111c and the attracting electrode 111d, and each of the substrate W and the edge ring 112a may be electrostatically attracted to the electrostatic chuck 111.

As a second example, in the separate electrostatic chuck 111 (see FIGS. 4 and 5), an RF source power and an RF bias power may be supplied to the base 122. In this case, a DC voltage may be supplied to each of the attracting electrode 111c and the attracting electrode 111d, and each of the substrate W and the edge ring 112a may be electrostatically attracted to the electrostatic chuck 111.

As a third example, in the integrated electrostatic chuck 111 (see FIG. 1), an RF source power and a pulsed DC bias power may be supplied from the power supply part 30 to the base 122. In this case, a DC voltage may be supplied to the attracting electrode 111c, and the substrate W may be electrostatically attracted to the electrostatic chuck 111.

As a fourth example, in the integrated electrostatic chuck 111 (see FIG. 1), an RF source power may be supplied from the power supply part 30 to the base 122, and a pulsed DC bias power may be supplied to the first bias electrode 111e. In this case, a DC voltage may be supplied to the attracting electrode 111c, and the substrate W may be electrostatically attracted to the electrostatic chuck 111.

As a fifth example, in the integrated electrostatic chuck 111 (see FIG. 1), an RF source power may be supplied from the power supply part 30 to the base 122, and a pulsed DC bias power (first DC bias power) may also be supplied to the first bias electrode 111e. Further, a pulsed DC bias power (second DC bias power) may be supplied to the second bias electrode 111h. In this case, a DC voltage may be supplied to each of the attracting electrode 111c and the attracting electrode 111d, and each of the substrate W and the edge ring 112a may be electrostatically attracted to the electrostatic chuck 111.

As a sixth example, in the separated electrostatic chuck 111 (see FIGS. 4 and 5), an RF source power may be supplied from the power supply part 30 to the base 122, and a pulsed DC bias power (first DC bias power) may be supplied to the first bias electrode 111e. Further, a pulsed DC bias power (second DC bias power) may be supplied to the second bias electrode 111h. In this case, a DC voltage may be supplied to each of the attracting electrode 111c and the attracting electrode 111d, and each of the substrate W and the edge ring 112a may be electrostatically attracted to the electrostatic chuck 111.

As a seventh example, in the integrated electrostatic chuck 111 (see FIG. 1), an RF source power and a pulsed DC bias power (first DC bias power) may be supplied from the power supply part 30 to the base 122. Further, a pulsed DC bias power (second DC bias power) may be supplied to the second bias electrode 111h. In this case, a DC voltage may be supplied to each of the attracting electrode 111c and the attracting electrode 111d, and each of the substrate W and the edge ring 112a may be electrostatically attracted to the electrostatic chuck 111.

As an eighth example, in the separated electrostatic chuck 111 (see FIGS. 4 and 5), an RF source power and a pulsed DC bias power (first DC bias power) may be supplied from the power supply part 30 to the base 122. Further, a pulsed DC bias power (second DC bias power) may be supplied to the second bias electrode 111h. In this case, a DC voltage may be supplied to each of the attracting electrode 111c and the attracting electrode 111d, and each of the substrate W and the edge ring 112a may be electrostatically attracted to the electrostatic chuck 111.

As a ninth example, in the integrated electrostatic chuck 111 (see FIG. 1), an RF source power and a pulsed DC bias power may be supplied from the power supply part 30 to the base 122. In this case, a DC voltage may be supplied to each of the attracting electrode 111c and the attracting electrode 111d, and each of the substrate W and the edge ring 112a may be electrostatically attracted to the electrostatic chuck 111.

In accordance with the substrate supports 11 according to the first and second embodiments and the substrate processing apparatus including the same, it is possible to increase the heat transfer efficiency between the low linear expansion coefficient member 114 and the base 122. Accordingly, it is possible to improve the cooling performance of the channel 123, promote the decrease in the temperature of the substrate W, and control the temperature of the substrate W with high accuracy. Further, the processing cost can be lowered compared to the substrate support 11′ of the reference example shown in FIG. 2A.

Although the cooling of the substrate W by the heat exchange medium has been mainly described in the above embodiments, the temperature adjustment such as heating of the substrate W by the heat exchange medium may be performed. In this case, it is also possible to promote the temperature increase (temperature adjustment) of the substrate W and control the temperature of the substrate W with high accuracy.

The above-described embodiments include, for example, the following aspects.

### APPENDIX 1

A substrate processing apparatus comprising:
a processing chamber;
a substrate support disposed in the processing chamber; and
a power supply configured to supply a radio frequency (RF) power to at least the substrate support,
wherein the substrate support includes:
an electrostatic chuck that is made of ceramic and holds a substrate to be processed by electrostatic attraction;
a base that has a channel through which a heat exchange medium flows and supports the electrostatic chuck;
a low linear expansion coefficient member disposed between the electrostatic chuck and the base;
a heat transfer sheet disposed between the low linear expansion coefficient member and the base;
a fixing part configured to fix the heat transfer sheet to the low linear expansion coefficient member; and
a conductive member that is disposed between the low linear expansion coefficient member and the base and electrically connects the low linear expansion coefficient member and the base.

### APPENDIX 2

The substrate processing apparatus of Appendix 1, wherein an upper surface of the channel is blocked by the low linear expansion coefficient member.

### APPENDIX 3

The substrate processing apparatus of Appendix 1, wherein an upper surface of the channel is blocked at an upper part of the base.

### APPENDIX 4

The substrate processing apparatus of any one of Appendices 1 to 3, further comprising:
a metal bonding layer that metal-bonds the electrostatic chuck and the low linear expansion coefficient member.

### APPENDIX 5

The substrate processing apparatus of any one of Appendices 1 to 4, wherein the fixing part has a screw structure or a clamp structure.

### APPENDIX 6

The substrate processing apparatus of any one of Appendices 1 to 5, wherein the low linear expansion coefficient member is made of a material whose linear expansion coefficient difference from the electrostatic chuck is 2 ppm/° C. or less.

### APPENDIX 7

The substrate processing apparatus of any one of Appendices 1 to 6, wherein the low linear expansion coefficient member is metal matrix composites or molybdenum.

### APPENDIX 8

The substrate processing apparatus of any one of Appendices 1 to 7, wherein the base is made of a material having a volume resistivity of less than 10⁻⁴ Ωm.

### APPENDIX 9

The substrate processing apparatus of any one of Appendices 1 to 8, wherein the base is made of aluminum, molybdenum, or titanium.

### APPENDIX 10

The substrate processing apparatus of any one of Appendices 1 to 9, wherein the heat transfer sheet is a graphite sheet.

### APPENDIX 11

The substrate processing apparatus of any one of Appendices 1 to 10, wherein the power supply is configured to supply an RF source power, and an RF bias power or a DC bias voltage to the base.

### APPENDIX 12

The substrate processing apparatus of any one of Appendices 1 to 11, wherein the electrostatic chuck has a first portion having a substrate supporting surface configured to support the substrate to be processed, and a second portion having a ring supporting surface configured to support an edge ring to surround the substrate to be processed, and
the power supply is configured to supply an RF source power to the base, and supply an RF bias power or a DC bias voltage to an electrode disposed at the first portion and/or the second portion of the electrostatic chuck.

### APPENDIX 13

The substrate processing apparatus of Appendix 12, wherein the first portion and the second portion of the electrostatic chuck are integrated.

### APPENDIX 14

The substrate processing apparatus of Appendix 12, wherein the first portion and the second portion of the electrostatic chuck are separated.

### APPENDIX 15

The substrate processing apparatus of Appendix 14, further comprising a metal bonding layer that metal-bonds the electrostatic chuck and the low linear expansion coefficient member, wherein the metal bond is separated to correspond to a separation position between the first portion and the second portion of the electrostatic chuck.

### APPENDIX 16

The substrate processing apparatus of Appendix 15, wherein the low linear expansion coefficient member is separated to correspond to a position where the metal bonding layer is separated.

### APPENDIX 17

The substrate processing apparatus of Appendix 16, wherein the base is separated to correspond to a position where the low linear expansion coefficient member is separated.

### APPENDIX 18

A substrate support disposed in a processing chamber of a substrate processing apparatus, comprising:
an electrostatic chuck that is made of ceramic and holds a substrate to be processed by electrostatic attraction;
a base that has a channel through which a heat exchange medium flows and supports the electrostatic chuck;
a low linear expansion coefficient member disposed between the electrostatic chuck and the base;
a heat transfer sheet disposed between the low linear expansion coefficient member and the base;
a fixing part configured to fix the heat transfer sheet to the low linear expansion coefficient member; and
a conductive member that is disposed between the low linear expansion coefficient member and the base and electrically connects the low linear expansion coefficient member and the base.

The present disclosure is not limited to the configuration described in the above embodiments, and other components can be combined with the configuration described in the above embodiments. The above embodiments can be modified without departing from the scope of the present disclosure, and can be appropriately determined according to the form of the application. The above-described embodiments may include other configurations without contradicting each other and may be combined without contradicting each other.

For example, although a capacitively coupled plasma processing apparatus has been described as an example of the substrate processing apparatus in the above embodiments, the present disclosure is not limited thereto, and may be applied to another substrate processing apparatus. For example, an inductively coupled plasma (ICP) processing apparatus may be used instead of the capacitively coupled plasma processing apparatus. In this case, the inductively coupled plasma processing apparatus includes an antenna and a lower electrode. The lower electrode is disposed in the substrate support, and the antenna is disposed at the upper portion of the chamber or above the chamber. Further, an RF generator is connected to the antenna, and a DC generator is connected to the lower electrode. Therefore, the RF generator is connected to the upper electrode of the capacitively coupled plasma processing apparatus or to the antenna of the inductively coupled plasma processing apparatus. In other words, the RF generator is connected to the plasma processing chamber 10.

1. A substrate processing apparatus comprising:
a processing chamber;
a substrate support disposed in the processing chamber; and
a power supply configured to supply a radio frequency (RF) power to at least the substrate support,
wherein the substrate support includes:
an electrostatic chuck that is made of ceramic and holds a substrate to be processed by electrostatic attraction;
a base that has a channel through which a heat exchange medium flows and supports the electrostatic chuck;
a low linear expansion coefficient member disposed between the electrostatic chuck and the base;
a heat transfer sheet disposed between the low linear expansion coefficient member and the base;
a fixing part configured to fix the heat transfer sheet to the low linear expansion coefficient member; and
a conductive member that is disposed between the low linear expansion coefficient member and the base and electrically connects the low linear expansion coefficient member and the base.

2. The substrate processing apparatus of claim 1, wherein an upper surface of the channel is blocked by the low linear expansion coefficient member.

3. The substrate processing apparatus of claim 1, wherein an upper surface of the channel is blocked at an upper part of the base.

4. The substrate processing apparatus of claim 1, further comprising:
a metal bonding layer that metal-bonds the electrostatic chuck and the low linear expansion coefficient member.

5. The substrate processing apparatus of claim 1, wherein the fixing part has a screw structure or a clamp structure.

6. The substrate processing apparatus of claim 1, wherein the low linear expansion coefficient member is made of a material whose linear expansion coefficient difference from the electrostatic chuck is 2 ppm/° C. or less.

7. The substrate processing apparatus of claim 1, wherein the low linear expansion coefficient member is metal matrix composites or molybdenum.

8. The substrate processing apparatus of claim 1, wherein the base is made of a material having a volume resistivity of less than 10⁻⁴ Ωm.

9. The substrate processing apparatus of claim 1, wherein the base is made of aluminum, molybdenum, or titanium.

10. The substrate processing apparatus of claim 1, wherein the heat transfer sheet is a graphite sheet.

11. The substrate processing apparatus of claim 1, wherein the power supply is configured to supply an RF source power, and an RF bias power or a DC bias voltage to the base.

12. The substrate processing apparatus of claim 1, wherein the electrostatic chuck has a first portion having a substrate supporting surface configured to support the substrate to be processed, and a second portion having a ring supporting surface configured to support an edge ring to surround the substrate to be processed, and
the power supply is configured to supply an RF source power to the base, and supply an RF bias power or a DC bias voltage to an electrode disposed at the first portion and/or the second portion of the electrostatic chuck.

13. The substrate processing apparatus of claim 12, wherein the first portion and the second portion of the electrostatic chuck are integrated.

14. The substrate processing apparatus of claim 12, wherein the first portion and the second portion of the electrostatic chuck are separated.

15. The substrate processing apparatus of claim 14, further comprising a metal bonding layer that metal-bonds the electrostatic chuck and the low linear expansion coefficient member, wherein the metal bond is separated to correspond to a separation position between the first portion and the second portion of the electrostatic chuck.

16. The substrate processing apparatus of claim 15, wherein the low linear expansion coefficient member is separated to correspond to a position where the metal bonding layer is separated.

17. The substrate processing apparatus of claim 16, wherein the base is separated to correspond to a position where the low linear expansion coefficient member is separated.

18. A substrate support disposed in a processing chamber of a substrate processing apparatus, comprising:
an electrostatic chuck that is made of ceramic and holds a substrate to be processed by electrostatic attraction;
a base that has a channel through which a heat exchange medium flows and supports the electrostatic chuck;
a low linear expansion coefficient member disposed between the electrostatic chuck and the base;
a heat transfer sheet disposed between the low linear expansion coefficient member and the base;
a fixing part configured to fix the heat transfer sheet to the low linear expansion coefficient member; and
a conductive member that is disposed between the low linear expansion coefficient member and the base and electrically connects the low linear expansion coefficient member and the base.
